(19) United States
(12) Patent Application Publication
(10) Pub. No.: US 2002/0182765 A1
(43) Pub. Date: Dec. 5, 2002

(54) Quantum well structures and methods of making the same

(76) Inventors: Chuong Tran, Bridgewater, NJ (US); Robert F. Karlicek JR., Flemington, NJ (US)

Correspondence Address: LERNER, DAVID, LITTENBERG,, KRUMHOLZ & MENTLIK, 600 SOUTH AVENUE WEST, WESTFIELD, NJ, 07090, US

(21) Appl. No.: 09/935,890

(22) Filed: Aug. 23, 2001

Related U.S. Application Data
(62) Division of application No. 09/437,538, filed on Nov. 10, 1999, now abandoned.
(60) Provisional application No. 60/108,593, filed on Nov. 16, 1998.

(51) Int. Cl. H01L 21/00

(52) U.S. Cl. 438/29; 438/46; 438/47

(57) ABSTRACT

In deposition of a quantum well structure for a light emitting diode, each well layer is formed by a two-phase process. In a first phase, relatively high flux rates of gallium and indium are employed. In the second phase, lower flux rates of gallium and indium are used. The well layer is formed with a composition which varies across the horizontal extent of the layer, and which typically includes clusters of indium-enriched material surrounded by regions of indium-poor material. The resulting structure exhibits enhanced brightness and a narrow, well-defined emission spectrum.

### CROSS-REFERENCE TO RELATED APPLICATIONS

The present application is a divisional of U.S. patent application Ser. No. 09/437,538, filed on Nov. 10, 1999, entitled QUANTUM WELL STRUCTURES AND METHODS OF MAKING THE SAME, which application claims benefit of U.S. Provisional Patent Application No. 60/108,593, filed Nov. 16, 1998, the disclosure of which is hereby incorporated by reference herein.

### BACKGROUND OF THE INVENTION

Light emitting diode structures typically include a layer of n-type semiconductor and a layer of p-type semiconductor forming a junction with the n-type semiconductor. The semiconductor layers are connected between a pair of electrodes so that an external bias voltage may be applied. When an appropriate bias voltage is applied, a current flows through the diode. The current is carried as electrons in the n-type semiconductor and electron vacancies or “holes” in the p-type semiconductor. The electrons and the holes flow toward the junction from opposite sides, and meet at or adjacent the junction. When the electrons and holes meet, they recombine with one another; the electrons fill the holes. Such recombination yields energy in the form of electromagnetic radiation such as infrared, visible or ultraviolet light. The wavelength of the electromagnetic radiation depends on properties of the semiconductor in the region where recombination occurs, such as the bandgap or difference in energy between certain states which electrons can assume in the material. It has long been known that emission properties of a diode structure can be enhanced by forming a so-called quantum well structure adjacent the p-n junction. The quantum well structure includes at least one very thin layer, typically a few atoms or a few tens of atoms thick, formed from a material having a relatively low bandgap disposed between layers of material having a higher bandgap. The low-bandgap layers are referred to as “well” layers, whereas the high bandgap layers are referred to as “barrier” layers. Electrons tend to be confined in the well layers by quantum effects related to the relatively small thickness dimensions of the well layer or layers. The quantum well structure typically provides enhanced emission efficiency and improved control of emission wavelength. In a single quantum well structure or “SQW” the two barrier layers may be integral with the p-type and n-type semiconductor layers. In a multiple quantum well or “MQW” structure, well layers and barrier layers are formed as a stack in alternating order. The well layers and barrier layers have been grown by conventional fabrication techniques with the objective of providing the best possible crystal quality and the most uniform possible composition throughout each layer.

The basic light-emitting diode structures described above typically are formed with ancillary structures. For example, the p-type and/or n-type layers may include transparent layers for transmitting light generated in the diode to the outside environment; reflective structures for reflecting the light. The p-type and/or n-type layers may also include cladding layers disposed adjacent the quantum well structure having a larger bandgap than the well layers, and typically a larger bandgap than the barrier layers, for confining carriers within the quantum well structures. Also, the basic light-emitting diode structure may be fabricated in a configuration suitable for use as a laser. Light-emitting diodes which can act as lasers are referred to as “laser diodes”. For example, a laser diode may have a quantum well structure extending in an elongated strip between the p-type and n-type structures, and the device may have current-confining structures disposed alongside of the strip so as to concentrate the current in the strip. The laser diode may also include additional elements such as light-confining layers disposed above or below the quantum well structure.

Light-emitting diodes have been fabricated heretofore from so-called III-V compound semiconductors, i.e. compounds of one or more elements in periodic table group III, such as gallium (Ga), aluminum (Al) and indium (In) with one or more elements in periodic table group V, such as nitrogen (N), phosphorous (P) and arsenic (As). In particular, the nitride semiconductors have been employed. As used in this disclosure, the term “nitride semiconductor” refers to a III-V compound semiconductor in which the group V element or elements is predominantly composed of N, with or without minor amounts of As, P or both. Most typically, the group V element consists entirely of N. The term “gallium nitride based semiconductor” refers to a nitride semiconductor in which the group III element one or more of Ga, In and Al. Preferably, a gallium nitride based semiconductor conforms to the formula AlₐIn_{b}Ga_{c}N, where a+b+c=1 and each of a, b and c is in the range from 0 to 1 inclusive. Light emitting diodes formed from gallium nitride based semiconductors can provide emission at various wavelengths in the visible and ultraviolet range. The bandgap of a gallium nitride based semiconductor is inversely related to the amount of In in the material. Therefore, light emitting diodes formed from gallium nitride based semiconductors heretofore have incorporated quantum well structures with well layers according to the formula In_{y}Ga_{1-y}N such that y>0, and with barrier layers according to the formula InₓGa₁₋ₓN, where x<y, inclusive of x=0. Here again, the well and barrier layers have been formed by conventional processes such as chemical vapor deposition, with the objective of providing uniform composition throughout the layer.

Despite all of the efforts in the art heretofore, still further improvement would be desirable.

### SUMMARY OF THE INVENTION

One aspect of the invention provides a quantum well structure for a light-emitting device. The quantum well structure according to this aspect of the invention includes one or more well layers, and two or more barrier layers. Each of these layers extend in horizontal directions, the layers being superposed on one another in alternating order so that each well layer is disposed between two barrier layers. The barrier layers have wider band gaps than the well layers. Most preferably, the well layers have average composition according to the formula In_{y}Ga_{1-y}N such that y>0. Most desirably, each well layer includes indium-rich clusters and indium-poor regions interspersed with one another across the horizontal extent of such well layer. Stated another way, the composition of the individual well layer is not uniform throughout the layer. The indium-rich regions, also referred to herein as “clusters”, have indium content greater than the average indium content of the well layer, whereas the indium-poor regions have indium content lower than the average indium content of the layer. The indium-rich regions desirably have minor horizontal dimensions of about 10 Å or more, and most desirably about 30-50 Å. The indium-rich clusters typically are surrounded by indium-poor regions.

Although the present invention is not limited by any theory of operation, it is believed that the indium-rich regions provide some additional quantum confinement of the electrons in the horizontal direction. Regardless of the mechanism of operation, the preferred quantum well structure with nonuniform well layers according to this aspect of the invention can provide enhanced light output and more precise wavelength control than the comparable structures with conventional well layers.

Most typically, the barrier layers have average composition according to the formula InₓGa₁₋ₓN, inclusive of x=0, with x<y. Preferably, x=0, and hence the barrier layers are GaN. The barrier layers desirably are between 30 and 300 Å thick, and the well layers desirably are between 10 and 100 Å thick. More preferably, the barrier layers are between 50 and 150 Å thick and the well layers are between 10 and 40 Å thick.

A further aspect of the invention provides a light-emitting device comprising a p-type III-V semiconductor, an n-type III-V semiconductor and a quantum well structure as aforesaid disposed between said p-type and n-type semiconductors. Preferably, the regions of the p-type and n-type semiconductors adjacent the quantum well structures are nitride semiconductors, most preferably those in accordance with the formula AlₐIn_{b}Ga_{c}N, inclusive of a=0, b=0 and c=0, where a+b+c=1.

A further aspect of the invention provides methods of making a quantum well structure for a light-emitting device. Methods according to this aspect of the invention desirably include the step of depositing a well layer from a first phase gas mixture during a first phase onto a first barrier layer of the formula InₓGa₁₋ₓN inclusive of x=0, the well layer having average composition according to the formula In_{y}Ga_{1-y}N such that y>x.

In a second phase occurring after the first phase, the well layer is held on the first barrier layer at a temperature of about 550-900° C. in contact with a second phase gas mixture. The gas mixtures and flow rates of the gas mixtures are selected so as to provide an indium flux during the second phase less than the indium flux during the first phase. The second phase is conducted for a time sufficient to cause the well layer to form indium-rich clusters and indium-poor regions distributed over the horizontal extent of the well layer. Most preferably, the process further includes the step of depositing a second barrier layer of the formula InₓGa₁₋ₓN inclusive of x=0 such that y>x over said well layer after the second phase. Desirably, the aforesaid steps are repeated in a plurality of cycles, so that the second barrier layer deposited in one cycle serves as the first barrier layer in the next cycle.

Most preferably, the second phase gas mixture has a ratio of indium to gallium less than the ratio of indium to gallium in said first phase gas mixture, and the well layer undergoes a net loss of indium during the second phase. The first phase gas mixture desirably includes an organogallium compound such as a lower alkyl gallium compound, most preferably tetramethyl gallium (“TMG”), an organoindium compound, most preferably a lower alkyl indium compound such as tetramethyl indium (“TMI”) and ammonia, NH₃.

A method of making a quantum well structure for a light emitting device according to a further aspect of the invention desirably includes the step of depositing a well layer in a first phase. The well layer deposited during this first phase has having average composition according to the formula In_{y}Ga_{1-y}N where y>0. This layer is deposited by passing a first phase gas mixture including as components an organogallium compound, an organoindium compound and NH₃ over a first barrier layer of the formula InₓGa₁₋ₓN inclusive of x=0, such that y>x while maintaining the first barrier layer at about 550-900° C. Each of the components in the gas mixture has a first phase flux during the first phase.

The method according to this aspect of the invention also includes a second phase. During the second phase, the well layer is maintained at about 550-900° C. in the reactor while passing a second phase gas mixture including the aforementioned components over the surface so as to provide a second-phase flux of said organoindium compound lower than the first phase flux of said organoindium compound and a second phase flux of said organogallium compound lower than the first phase flux of said organogallium compound. Although the present invention is not limited by any theory of operation, it is believed that during the first phase, the relatively indium-rich regions are seeded at various locations in the deposited layer, and that these regions grow during the second phase. Thus, the first phase can be regarded as a “seeding” or deposition phase, whereas the second phase can be regarded as a “growth” phase.

Here again, the method may further include the step of depositing a second barrier layer of the formula InₓGa₁₋ₓN inclusive of x=0 such that y>x over the well layer after the second phase. These steps can be repeated in a plurality of cycles, so that the second barrier layer deposited in one cycle serves as the first barrier layer in the next cycle.

Here again, the organoindium and organogallium compounds desirably are lower alkyl indium and gallium compounds. The first phase gas mixture and second phase gas mixture desirably include N₂ in addition to the aforementioned components. The first phase flux of the organoindium compound desirably is about 0.3 to about 0.4 micromoles of indium per cm² per minute, whereas the first phase flux of said organogallium compound desirably is about 0.4 to about 0.6 micromoles of gallium per cm² per minute. The second phase flux of the organoindium compound desirably is about 0.15 to about 0.3 micromoles of indium per cm² per minute, and the second phase flux of the organogallium compound desirably is about 0.3 to about 0.4 micromoles of gallium per cm² per minute. Preferably, the ratio of the second phase organoindium flux to the second phase organogallium flux is less than the ratio of the first phase organoindium flux to the first phase organogallium flux.

The first phase desirably is continued for between about 0.05 minutes and about 0.5 minutes and the second phase desirably is continued for about 0.1 minutes to about 1.0 minutes.

### BRIEF DESCRIPTION OF THE DRAWINGS

FIG. 1 is a diagrammatic elevational view of a light emitting diode according to one embodiment of the invention.

FIG. 2 is a fragmentary, diagrammatic elevational view on an enlarged scale of the area indicated in FIG. 1.

FIG. 3 is a fragmentary, idealized plan view of a well layer included in the diode of FIGS. 1-2.

FIG. 4 is a graph depicting process conditions used in a method according to a further embodiment of the invention.

FIG. 5 is an emission spectrum of a diode in accordance with an embodiment of the invention.

FIG. 6 is an emission spectrum of a conventional diode.

### DETAILED DESCRIPTION OF THE PREFERRED EMBODIMENTS

A diode according to one embodiment of the invention is illustrated in FIG. 1. It includes a layer of an n-type III-V semiconductor 10, a layer of a p-type III-V semiconductor 12, and ohmic contact electrodes 14 and 16 electrically connected to the n and p layers. A quantum well structure 18 is disposed between the n-type and p-type layers. Preferably, at least those portions of the n-type and p-type layers abutting quantum well structure 18 are nitride semiconductors, most preferably those in accordance with the formula AlₐIn_{b}Ga_{c}N, inclusive of a=0, b=0 and c=0, where a+b+c=1. The n-type and p-type layers need not be of uniform composition, and may be formed in accordance with well-known practices in the art. Merely by way of example, the p-type layer may include a cladding layer 20 of a relatively high-bandgap nitride semiconductor such as Mg-doped AlGaN, i.e., AlₐIn_{b}Ga_{c}N where a>0, b=0 and c>0 overlying the MQW structure; a layer 22 of an Mg-doped nitride semiconductor such as GaN (AlₐIn_{b}Ga_{c}N where a=0, b=0, c=1), and a highly-doped GaN contact layer 24. The n-type layer may be provide on a substrate such as sapphire or other conventional growth substrate (not shown) and may incorporate a buffer region 26 of undoped GaN or AlGaN at the bottom, remote from the MQW structure and a main region of an Si-doped nitride semiconductor such as GaN or AlGaN 28 at the top, abutting the MQW structure.

The ohmic contacts 14 and 16 also may be conventional. For example, contact 14 on the n-type layer may include a layer of aluminum over a layer of titanium, whereas the ohmic contact 16 on the p-type layer may include nickel and gold. A transparent conductive layer 30 may be provided over a surface of the diode as, for example, on the top surface of the p-type layer, so that the transparent conductive layer is connected to contact 16. The transparent conductive layer helps to spread the current across the horizontal extent of the device.

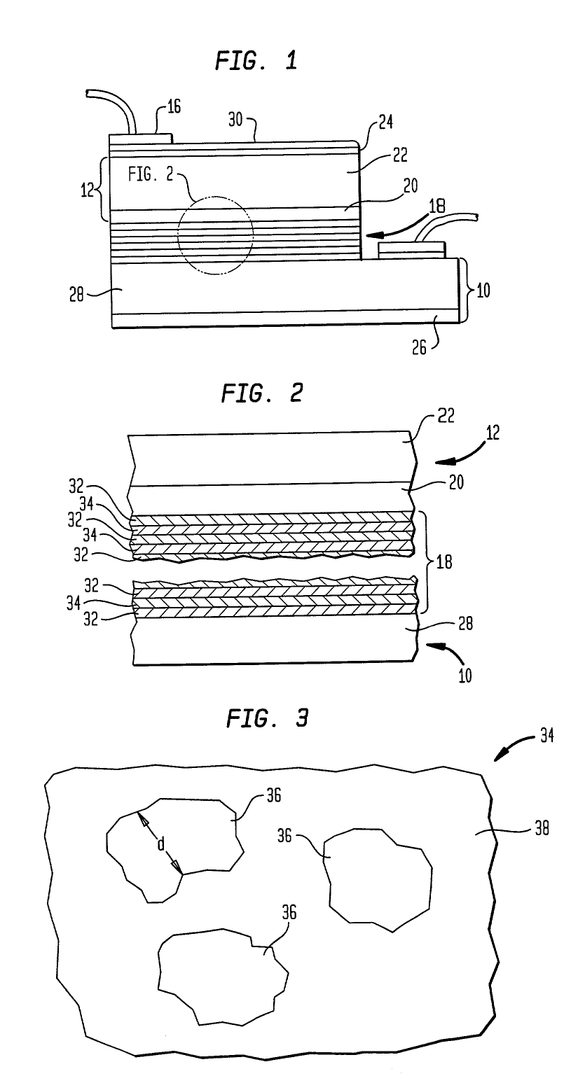

The quantum well structure 18 includes an alternating sequence of barrier layers 32 and well layers 34 vertically superposed on one another as shown in FIG. 2. Thus, each well layer lies between a first barrier layer on one side of the well layer and a second barrier layer on the other side of the well layer. Typically, about 1 to about 30 well layers are provided in the quantum well structure. The barrier layers 32 have wider band gaps than the well layers 34. The barrier layers typically are formed from a material according to the formula InₓGa₁₋ₓN inclusive of x=0, most typically pure GaN, i.e., x=0. The well layers have an average or overall composition according to the formula In_{y}Ga_{1-y}N such that y is greater than x and hence y is greater than 0. Most typically having a value of y between about 0.05 and about 0.9.

It has now been found according to the present invention that the emission intensity of such a device may be greatly enhanced by controlling the conditions used to form the quantum well and, in particular, the conditions used to form the well layers. The barrier layers and well layers preferably are deposited by organometallic vapor deposition, most preferably using gas mixtures containing lower alkyl indium and gallium compounds, most typically with NH₃ and preferably with N₂ to stabilize the layers against loss of nitrogen and with a carrier gas such as H₂. Deposition of the barrier layers desirably takes place at about 850-1000° C., whereas formation of the well layers typically takes place at about 500-950° C., as, for example, at 700-850° C.

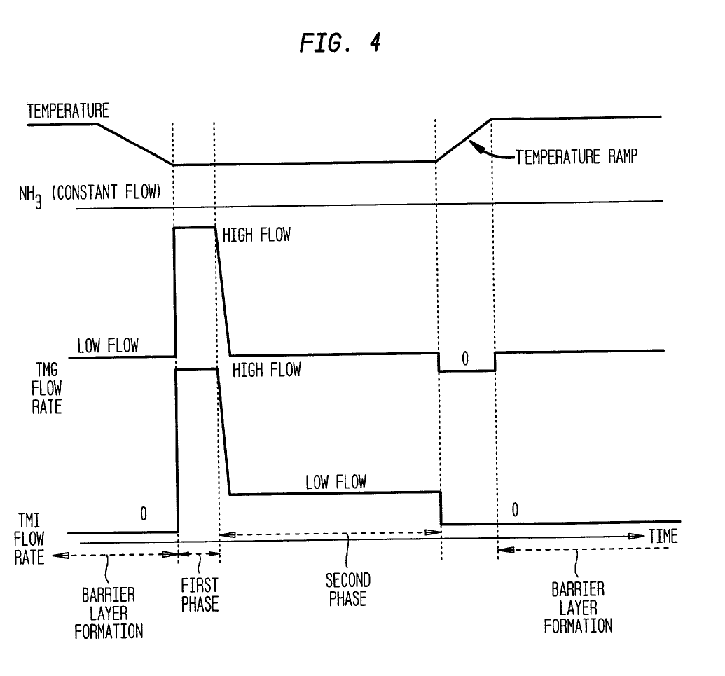

In preferred processes according to the present invention, formation of each well layer takes place in two distinct phases. In the first phase, relatively high flow rates of the organogallium and organoindium compounds are provided in a first-phase gas mixture. This continues for about 0.05 to about 0.5 minutes, depending on the organometallic flux provided in this phase. Following the first phase, the flow rates of the organogallium and organoindium compounds, and hence the flux of such compounds per unit area of the growing layer per unit time, are reduced. In the second phase of the growth procedure, the well layer being formed is maintained in contact with a second-phase gas mixture having a composition different from the first-phase gas mixture. This second phase desirably continues for about 0.1 to about 1.0 minutes. Following the second phase, a barrier layer is grown over the formed well layer, and the sequence of operations repeats, with the new well layer being deposited onto the last-formed barrier layer. One cycle of the process is depicted in FIG. 4.

A typical set of flux values for a process in accordance with one embodiment of the invention is set forth in Table I, below. The flux values are stated in micromoles per cm² of area of the growing layer per minute.

| | WELL LAYER | | BARRIER |
|---|---|---|---|
| REACTANT | FIRST PHASE | SECOND PHASE | LAYER GROWTH |
| TMG | 0.5 | 0.035 | 0.035 |
| TMI | 0.36 | 0.022 | 0 |
| NH₃ | 8500 | 8500 | 8500 |
| N₂ | 4250 | 4250 | 4250 |

During the second phase, the well layer being formed typically loses some indium by evaporation into the second phase gas mixture.

The composition of the resulting well layer 34 is not uniform throughout the horizontal extent of the layer. As shown diagrammatically in FIG. 3, each well layer 34 exhibits a planar inhomogeneous structure with clusters of material an having indium content higher than the average indium content of the whole layer, referred to herein as “indium-rich” clusters or regions 36, distributed throughout the layer and surrounded by a region 38 of material with lower indium content, referred to herein as “indium-poor” material. This effect should be clearly distinguished from the formation of a superlattice, observed in some ternary alloys. In a super lattice, compositional variations recur on a regular, repeating pattern and at repeat distances of a few unit cells of the crystal lattice. In the inhomogeneous layers according to the present invention, the clusters typically have smallest horizontal dimensions (d, FIG. 3), referred to herein as minor dimensions of about 10 Å or more. The indium rich clusters typically are randomly distributed. Although the present invention is not limited by any theory of operation, it is believed that these clusters arise by deposition or “seeding” of the surface with indium-rich material during the first phase and growth of the indium-rich cluster during the second phase.

The barrier layers typically have uniform composition through their horizontal extent.

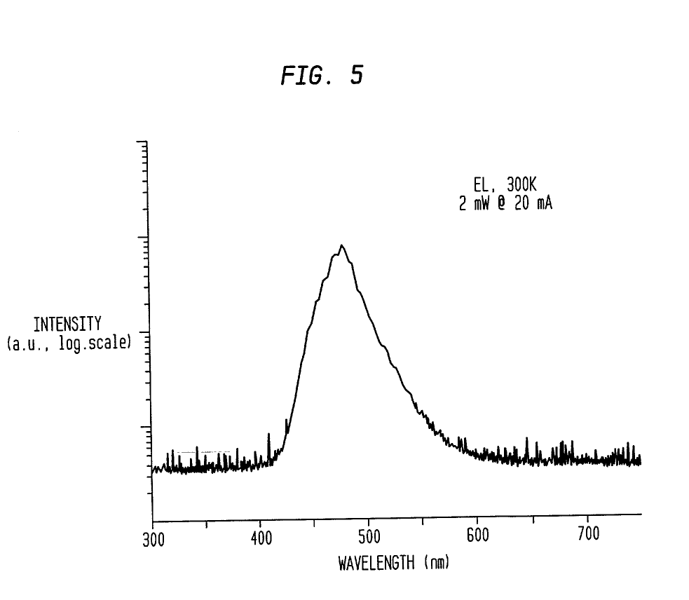

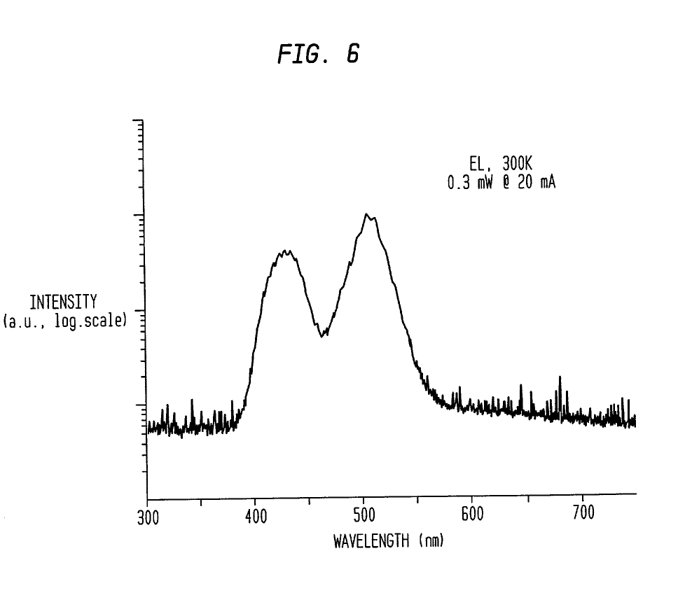

The resulting quantum well structure has a high emission brightness. The emission wavelength typically is about 370-600 nm, depending on the composition of the layers. For example, the emission spectrum of FIG. 5, taken from a device made in accordance with one embodiment of the invention, shows emission at a desired blue-green wavelength (about 470 mm). By contrast, similar quantum well structures made using a process with a uniform flow rates of organoindium and organogallium compounds during the well layer formation do not exhibit the inhomogeneous composition discussed above. LED's incorporating these quantum layer structures emit less intense radiation with an undesirable, twin-peak emission spectrum (FIG. 6).

Numerous variations and combinations of the features described above can be utilized. For example, some aluminum can be incorporated in well layers and barrier layers, in barrier layers or both. Also, the invention can be applied with some substitution of As and/or P for N. Stated another way, the well layers may have composition Al_{d}InₑGa_{f}NⱼAsₖPₗ, where d+e+f=1; 0≦d≦1; 0<e<1; 0≦f≦1; and j+k+l=1. The barrier layers each may have composition Al_{g}InₕGaᵢNₘAsₙPₒ, where g+h+i=1; 0≦g≦1; 0≦h<1; 0≦i≦1; and m+n+o=1. Desirably, the aluminum content d of the well layers is less than or equal to the aluminum content g of the barrier layers, and most desirably d and g are both about 0.2 or less. Also, the aggregate As and P content of the well layers and barrier layers desirably is less than about 20%, i.e., (k+l)≦0.2 and (n+o)≦0.2.

Quantum well structures and fabrication methods as discussed above can be used in making light emitting diode structures of various types. Thus, all of the conventional elements incorporated in conventional light emitting diodes, including laser diodes, may be employed.

As these and other variations and combinations of the features set forth below can be utilized without departing from the present invention, the foregoing description of the preferred embodiments should be taken by way of illustration, rather than by way of limitation, of the invention.

1. A method of making a quantum well structure for a light-emitting device comprising the steps of:
a) in a first phase, depositing a well layer having average composition according to the formula InyGa1-yN from a first phase gas mixture onto a first barrier layer of the formula InxGa1-xN inclusive of x=0, such that y>x; and then
b) in a second phase, holding said well on said base layer at a temperature of about 550-900° C. in contact with a second phase gas mixture, said gas mixtures and flow rates of said gas mixtures being selected so as to provide an indium flux during the second phase less than the indium flux during the first phase, said second phase being conducted for a time sufficient to cause said well layer to form indium-rich clusters and indium-poor regions distributed over the horizontal extent of the well layer.

2. A method as claimed in claim 1 further comprising the step of depositing a second barrier layer of the formula InxGa1-xN inclusive of x=0 such that y>x over said well layer after said second phase.

3. A method as claimed in claim 2 further comprising the step of repeating the aforesaid steps in a plurality of cycles, so that the second barrier layer deposited in one cycle serves as the first barrier layer in the next cycle.

4. A method as claimed in claim 1 wherein said second phase gas mixture has a ratio of indium to gallium less than the ratio of indium to gallium in said first phase gas mixture.

5. A method as claimed in claim 1 wherein said well layer undergoes a net loss of indium during said second phase.

6. A method as claimed in claim 4 wherein said first phase gas mixture includes an organogallium compound, an organoindium compound and NH3.

7. A method of making a quantum well structure for a light emitting device comprising the steps of:
a) in a first phase, depositing a well layer having average composition according to the formula InyGa1-yN by passing a first phase gas mixture including as components an organogallium compound, an organoindium compound and NH3 over a first barrier layer of the formula InxGa1-xN inclusive of x=0, such that y>x while maintaining said first barrier layer at about 550-900° C., whereby each of said components has a first phase flux during said first phase; and then
b) in a second phase, maintaining said well layer at about 550-900° C. in said reactor while passing a second phase gas mixture including said components over said surface so as to provide a second-phase flux of said organoindium compound lower than the first phase flux of said organoindium compound and a second phase flux of said organogallium compound lower than the first phase flux of said organogallium compound.

8. A method as claimed in claim 7 further comprising the step of depositing a second barrier layer of the formula InxGa1-xN inclusive of x=0 such that y>x over said well layer after said second phase.

9. A method as claimed in claim 8 further comprising the step of repeating the aforesaid steps in a plurality of cycles, so that the second barrier layer deposited in one cycle serves as the first barrier layer in the next cycle.

10. A method as claimed in claim 8 wherein said organoindium and organogallium compounds are lower alkyl indium and gallium compounds.

11. A method as claimed in claim 8 wherein said first phase gas mixture and second phase gas mixture include N_{2.}

12. A method as claimed in claim 8 wherein said first phase flux of said organoindium compound is about 0.3 to about 0.4 micromoles per cm² per minute; said first phase flux of said organogallium compound is about 0.4 to about 0.6 micromoles per cm² per minute.

13. A method as claimed in claim 10 wherein said second phase flux of said organoindium compound is about 0.15 to about 0.3 micromoles per cm² per minute and said second phase flux of said organogallium compound is about 0.3 to about 0.4 micromoles per cm² per minute.

14. A method as claimed in claim 8 wherein said first phase is continued for between about 0.05 minutes and about 0.5 minutes and said second phase is continued for about 0.1 minutes to about 1.0 minutes.

15. A method as claimed in claim 8 wherein the ratio of said second phase organoindium flux to said second phase organogallium flux is less than the ratio of said first phase organoindium flux to said first phase organogallium flux.

16. A method of making a quantum well structure for a light-emitting device comprising the steps of:
a) in a first phase, depositing a well layer having average composition according to the formula Al_{d}InₑGa_{f}NⱼAsₖPₗ, where d+e+f=1; 0≦d≦1; 0<e<1; 0≦f≦1; and j+k+l=1, from a first phase gas mixture onto a first barrier layer of the formula Al_{g}InₕGaᵢNₘAsₙPₒ, where g+h+i=1; 0≦g≦1; 0≦h≦1; 0≦i≦1; and m+n+o=1 and e>h; and then
b) in a second phase, holding said well on said base layer at a temperature of about 550-900° C. in contact with a second phase gas mixture, said gas mixtures and flow rates of said gas mixtures being selected so as to provide an indium flux during the second phase less than the indium flux during the first phase, said second phase being conducted for a time sufficient to cause said well layer to form indium-rich clusters and indium-poor regions distributed over the horizontal extent of the well layer.

17. A method as claimed in claim 16 further comprising the step of depositing a second barrier layer as aforesaid over said well layer after said second phase.

18. A method as claimed in claim 17 further comprising the step of repeating the aforesaid steps in a plurality of cycles, so that the second barrier layer deposited in one cycle serves as the first barrier layer in the next cycle.
